(19) United States
(12) Patent Application Publication
(10) Pub. No.: US 2018/0219140 A1
(43) Pub. Date: Aug. 2, 2018

(54) LIGHT EMITTING DEVICE

(71) Applicant: TOYODA GOSEI CO., LTD., Kiyosu-shi (JP)

(72) Inventors: Satomi Seki, Kiyosu-shi (JP); Daisuke Kato, Kiyosu-shi (JP); Tomohiro Miwa, Kiyosu-shi (JP); Shigeo Takeda, Kiyosu-shi (JP); Shota Shimonishi, Kiyosu-shi (JP)

(21) Appl. No.: 15/820,270

(22) Filed: Nov. 21, 2017

(30) Foreign Application Priority Data
Feb. 1, 2017 (JP) 2017-017042

(51) Int. Cl. H01L 33/50

(52) U.S. Cl. CPC H01L 33/504; H01L 33/54; H01L 33/507

(57) ABSTRACT

A light emitting device includes a first phosphor group including at least two types of phosphors emitting a fluorescence having a peak emission wavelength of not less than 445 nm and not more than 490 nm, a second phosphor group including at least two types of phosphors emitting a fluorescence having a peak emission wavelength of not less than 491 nm and not more than 600 nm, a third phosphor group including at least two types of phosphors emitting a fluorescence having a peak emission wavelength of not less than 601 nm and not more than 670 nm, and a light emitting element emitting a light having a peak emission wavelength at a shorter wavelength side than the peak emission wavelength of the fluorescence emitted from the first phosphor group.

The present application is based on Japanese patent application No. 2017-017042 filed on Feb. 1, 2017, the entire contents of which are incorporated herein by reference.

### BACKGROUND OF THE INVENTION

### 1. Field of the Invention

This invention relates to a light emitting device.

### 2. Description of the Related Art

A light emitting diode (LED) module is known that emits light showing consecutive emission spectral distribution in the wavelength of not less than 380 nm and not more than 780 nm (see e.g. JP 2016/076652A).

The LED module described in JP 2016/076652A uses phosphors that are selected and combined by one phosphor from each blue phosphor, green phosphor, yellow phosphor, and red phosphor. The LED module can use two types of phosphors from the red phosphors, or five or six types of phosphors by additionally combining blue green phosphor having intermediate color.

### SUMMARY OF THE INVENTION

It is an object of the invention to provide a light emitting device that is excellent in color rendering property so as to emit a light closer to the sunlight than the light emitted from the known light emitting device.

According to an embodiment of the invention, a light emitting device defined by [1] to [4] below is provided.

A light emitting device, comprising:

a first phosphor group comprising at least two types of phosphors emitting a fluorescence having a peak emission wavelength of not less than 445 nm and not more than 490 nm;

a second phosphor group comprising at least two types of phosphors emitting a fluorescence having a peak emission wavelength of not less than 491 nm and not more than 600 nm;

a third phosphor group comprising at least two types of phosphors emitting a fluorescence having a peak emission wavelength of not less than 601 nm and not more than 670 nm; and

a light emitting element emitting a light having a peak emission wavelength at a shorter wavelength side than the peak emission wavelength of the fluorescence emitted from the first phosphor group.

[2] The light emitting device according to [1], wherein the peak emission wavelength of the light emitted from the light emitting element is not less than 410 nm and not more than 425 nm.

[3] The light emitting device according to [1] or [2], wherein the light emitting device emits a light of which color rendering indexes Rf and Rg satisfy Rf≥90 and 95≤Rg≤105, respectively, where a base light is defined by a light having a color temperature of not less than 5000K and not more than 6500K.

[4] The light emitting device according to any one of [1] to [3], wherein the first phosphor group comprises two types of alkaline earth halophosphate phosphors,

wherein the second phosphor group comprises β-SiAlON phosphor and Ca solid solution α-SiAlON phosphor, and

wherein the third phosphor group comprises CASON phosphor and CASN phosphor.

### Effects of the Invention

According to an embodiment of the invention, a light emitting device can be provided that is excellent in color rendering property so as to emit a light closer to the sunlight than the light emitted from the known light emitting device.

### BRIEF DESCRIPTION OF THE DRAWINGS

Next, the present invention will be explained in conjunction with appended drawings, wherein:

FIG. 1 is a vertical cross sectional view showing a light emitting device according to the embodiment;

FIG. 2 is a graph chart showing emission spectra of various alkaline earth halophosphate phosphors having different concentrations of an activator agent or alkaline earth metal;

FIG. 3A is a graph chart showing emission spectra of Ca solid solution α-SiAlON phosphor, β-SiAlON phosphor, Silicate phosphor, Nitride phosphor, LSN phosphor;

FIG. 3B is a graph chart showing emission spectra of YAG phosphor, and LuAG phosphor;

FIG. 4 is a graph chart showing emission spectra of CASN phosphor, SCASN phosphor, and CASON phosphor;

FIG. 5 is a graph chart showing emission spectra of two types of phosphors included in a first phosphor group, two types of phosphors included in a second phosphor group, and two types of phosphors included in a third phosphor group whose emission intensity are normalized;

FIG. 6 is a graph chart showing excitation spectra of two types of alkaline earth halophosphate phosphors, β-SiAlON phosphor, Ca solid solution α-SiAlON phosphor, CASON phosphor, and CASN phosphor;

FIG. 7 is a cross sectional view showing a modification of the light emitting device according to the embodiment; and

FIG. 8 is a graph chart showing emission spectra of an SMD type light emitting device of which the phosphor is included in sealing resin, and a COB type light emitting device of which the phosphor is included in a phosphor layer formed by coating.

### DETAILED DESCRIPTION OF THE PREFERRED EMBODIMENTS

### Embodiments

(Structure of a Light Emitting Device)

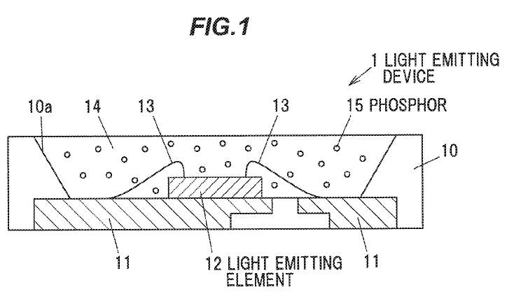

FIG. 1 is a vertical cross sectional view showing a light emitting device 1 according to the embodiment. The light emitting device 1 is provided with a case 10 having a recessed portion 10a, a lead frame 11 located in the case 10 so as to be exposed at a bottom of the recessed portion 10a, a light emitting element 12 mounted on the lead frame 11, bonding wire 13 electrically connecting the lead frame 11 and an electrode of the light emitting element 12, sealing resin 14 filled in the recessed portion 10a and sealing the light emitting element 12, and a particle phosphor 15 included in the sealing resin 14.

For example, the case 10 comprises heat plasticity resins such as polyphthalamide resin, a Liquid Crystal Polymer (LCP), and Polycyclohexylene Dimethylene Terephalate (PCT), and thermoset resins such as silicone resin, modified silicone resin, epoxy resin, and modified epoxy resin. The case 10 is formed by injection molding or transfer molding. The case 10 may comprise a light reflective particle such as titanium dioxide so as to improve optical reflectance.

For example, the whole or surface of the lead frame 11 comprises conductive materials such as Ag, Cu, and Al.

Typically, the light emitting element 12 is a light emitting diode (LED) element or a laser diode element. In the example shown in FIG. 1, the light emitting element 12 is a face-up type element connected to the lead frame 11 by the bonding wire 13. Meanwhile, the light emitting element 12 may be a face-down type element. The light emitting element 12 may be connected to the lead frame using a connecting member such as a conductive bump besides the bonding wire.

For example, the sealing resin 14 comprises resin material such as the silicone resin or the epoxy resin.

The phosphor 15 emits fluorescence by the light emitted from the light emitting element 12 as an excitation source. The phosphor 15 is provided with at least a first phosphor group including at least two types of phosphors that emit the fluorescence having the peak emission wavelength of not less than 445 nm and not more than 490 nm, a second phosphor group including at least two types of phosphors that emit the fluorescence having the peak emission wavelength of not less than 491 nm and not more than 600 nm, and a third phosphor group including at least two types of phosphors that emit the fluorescence having the peak emission wavelength of not less than 601 nm and not more than 670 nm such that an emission spectrum of the light emitting device 1 comes close to the emission spectrum of the sunlight. That is, the phosphor 15 is provided with at least six types of phosphors. Meanwhile, since the light emitting element 12 is the excitation source for the phosphor 15, the light emitting element 12 emits the light having the peak emission wavelength at shorter wavelength side of the peak emission wavelength of the fluorescence.

The first phosphor group is a blue phosphor group. For example, the first phosphor group includes alkaline earth halophosphate phosphor. Major component of alkaline earth halophosphate phosphor will be shown in Table 1 described below.

TABLE 1

| Phosphor | Main component |
|---|---|
| Alkaline earth halophosphate phosphor | (Ba,Sr,Ca,Mg)₅(PO₄)₃Cl:Eu²⁺ |
| | (Ba,Sr,Ca,Mg)₁₀(PO₄)₆Cl₂:Eu²⁺ |

Alkaline earth halophosphate phosphor can change the emission spectrum by changing concentrations of an activator agent such as Eu or alkaline earth metals such as Ca, Sr, Ba, and Mg.

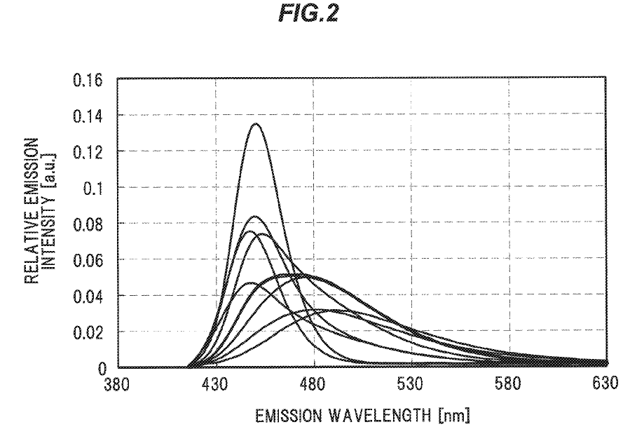

FIG. 2 is a graph chart showing emission spectra of various alkaline earth halophosphate phosphors having different concentrations of the activator agent or alkaline earth metal.

The second phosphor group is a yellow green phosphor group. For example, the second phosphor group includes Ca solid solution α-SiAlON phosphor, β-SiAlON phosphor, Silicate phosphor, Nitride phosphor, LSN phosphor, YAG phosphor, or LuAG phosphor. Major components of these phosphors will be shown in Table 2 described below.

TABLE 2

| Phosphor | Main component |
|---|---|
| Ca solid solution α-SiAlON phosphor | Ca—Si₁₂₋₍ₘ₊ₙ₎Alₘ₊ₙOₙN₁₆₋ₙ |
| β-SiAlON phosphor | Si_{6-z}Al_{z}O_{z}N_{8-z}:Eu²⁺ |
| Silicate phosphor | (Ca,Sr,Ba)₃SiO₅:Eu²⁺ |
| | (Ba,Sr,Ca)₂SiO₄:Eu²⁺ |
| Nitride phosphor | (Ca,Sr,Ba)₂Si₅N₈:Eu²⁺ |
| LSN phosphor | (La,Ca)₃Si₆N₁₁:Ce³⁺ |
| YAG phosphor | (Y,Gd)₃(Al,Ga)₅O₁₂:Ce³⁺ |
| LuAG phosphor | Lu₃(Al,Ga)₅O₁₂:Ce³⁺ |

YAG phosphor, LuAG phosphor can change the emission spectra by changing concentrations of Gd, Ga, and the activator agent such as Ce.

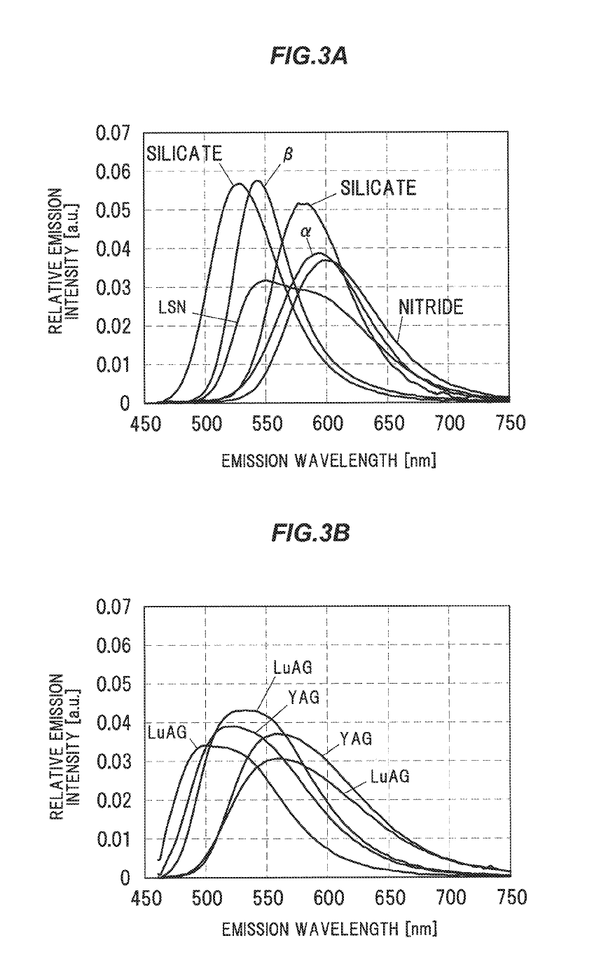

FIGS. 3A, 3B are graph charts showing emission spectra of Ca solid solution α-SiAlON phosphor, β-SiAlON phosphor, Silicate phosphor, Nitride phosphor, LSN phosphor, YAG phosphor, and LuAG phosphor. In FIG. 3A, “α”, “β”, “Silicate”, “Nitride”, and “LSN” respectively mean Ca solid solution α-SiAlON phosphor, β-SiAlON phosphor, Silicate phosphor, Nitride phosphor, and LSN phosphor. In FIG. 3B, “YAG”, “LuAG” respectively mean YAG phosphor and LuAG phosphor.

The third phosphor group is a red phosphor group. For example, the third phosphor group includes CASN phosphor, SCASN phosphor, or CASON phosphor.

Major components of these phosphors will be shown in Table 3 described below.

TABLE 3

| Phosphor | Main component |
|---|---|
| CASN phosphor | CaAlSiN₃:Eu²⁺ |
| SCASN phosphor | (Sr,Ca)AlSiN₃:Eu²⁺ |
| CASON phosphor | Ca₁₋ₓAl₁₋ₓSi₁₊ₓN₃₋ₓOₓ:Eu²⁺ |

CASN phosphor, SCASN phosphor, and CASON phosphor can change the emission spectra by changing concentrations the activator agent such as Eu, or alkaline earth metal such as Ca and Sr.

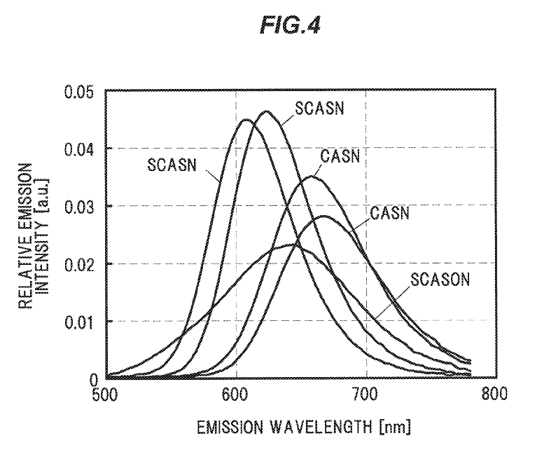

FIG. 4 is a graph chart showing emission spectra of CASN phosphor, SCASN phosphor, and CASON phosphor.

Combinations and ratio of concentration of the phosphors included in the phosphor 15 are adjusted such that the emission spectrum of the light emitting device 1 comes close to the emission spectrum of the sunlight, for example, such that color rendering indexes Rf, Rg come close to 100 when the sunlight in the morning of which color temperature is not less than 5000K and not more than 6500K is defined as a base light. Combinations and ratio of concentration of the phosphors included in the phosphor 15 are desirably adjusted such that the color rendering indexes Rf, Rg of the light emitted from the light emitting device 1 satisfies Rf≥90 and 95≤Rg≤105 when the light of which the color temperature is not less than 5000K and not more than 6500K is defined as the base light.

The above color rendering indexes Rf, Rg are defined by the color rendering indexes used in a new light color rendering property evaluation method “TM-30-15” defined by the Illuminating Engineering Society of North America (IES).

The Rf is a parameter indicating color fidelity. The Rf can evaluate the color fidelity in higher accuracy than the general color rendering index Ra since the Rf can be obtained by 99 types of color tests. The maximum of the Rf is defined as 100. It means that the color of the test light comes close to the color of the base light such as the sunlight when the Rf comes close to 100.

The Rg is a parameter indicating color brightness that is not evaluated in the known evaluation method. As the Rg comes close to 100, the color brightness of the test light comes close to the color brightness of the base light such as the sunlight. The Rg may be less than 100 or more than 100.

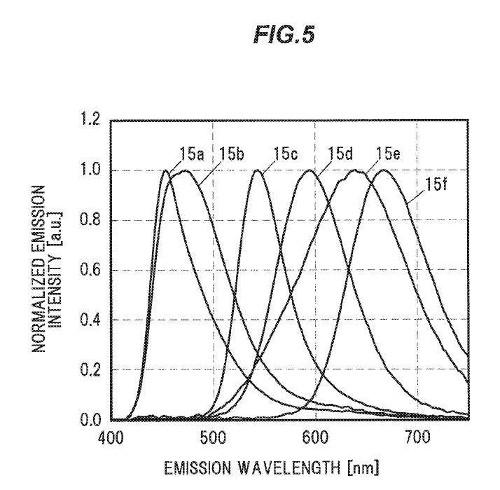

FIG. 5 is a graph chart showing emission spectra of two types of phosphors included in a first phosphor group, two types of phosphors included in a second phosphor group, and two types of phosphors included in a third phosphor group whose emission intensity are normalized. These phosphors are excited by the light having emission wavelength of 405 nm so as to measure the emission spectra shown in FIG. 5.

In the example shown in FIG. 5, alkaline earth halophosphate phosphors 15a, 15b are used as the phosphors included in the first phosphor group, β-SiAlON phosphor 15c and Ca solid solution α-SiAlON phosphor 15d are used as the phosphors included in the second phosphor group, CASON phosphor 15e and CASN phosphor 15f are used as the phosphors included in the third phosphor group. Table 4 described below shows properties of these phosphors included in the phosphor 15.

TABLE 4

| | | FWHM | | |
|---|---|---|---|---|
| | Peak | (full-width | | |
| | emission | at half- | | |
| | wavelength | maximum) | Chromaticity | |
| | (nm) | (nm) | x | y |
| Alkaline earth | 454 | 53 | 0.162 | 0.155 |
| halophosphate phosphors | | | | |
| 15a | | | | |
| Alkaline earth | 473 | 81 | 0.167 | 0.236 |
| halophosphate phosphors | | | | |
| 15b | | | | |
| β-SiAlON phosphor 15c | 544 | 55 | 0.364 | 0.615 |
| Ca solid solution α-SiAlON | 594 | 84 | 0.546 | 0.444 |
| phosphor 15d | | | | |
| CASON phosphor 15e | 639 | 125 | 0.576 | 0.417 |
| CASN phosphor 15f | 668 | 93 | 0.689 | 0.315 |

Thus, the emission spectrum of the light emitting device 1 can come close to the emission spectrum of the sunlight by using the two types of phosphors included in the first phosphor group, the two types of phosphors included in the second phosphor group, and the two types of phosphors included in the third phosphor group.

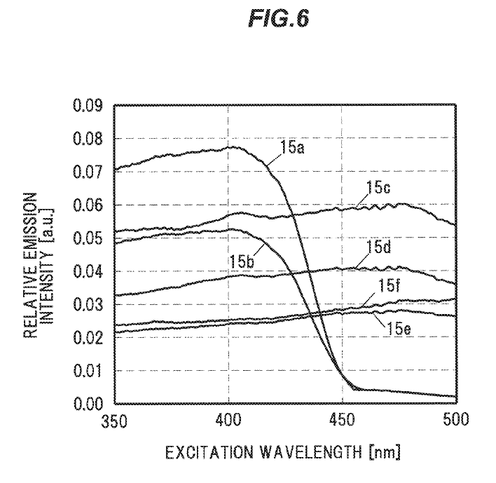

FIG. 6 is a graph chart showing excitation spectra of alkaline earth halophosphate phosphors 15a, 15b, β-SiAlON phosphor 15c, Ca solid solution α-SiAlON phosphor 15d, CASON phosphor 15e, and CASN phosphor 15f. FIG. 6 shows that these phosphors are effectively excited by the light having the emission wavelength of approximately not more than 425 nm. Thus, the peak emission wavelength of the light emitted from the light emitting element 12 that is the excitation source for the phosphor 15 is desirably not more than 425 nm.

The light having the emission wavelength of approximately not more than 425 nm can effectively excite the phosphors included in the first, second, and third phosphor groups when the phosphor emitting the fluorescence having the peak emission wavelength of not less than 445 nm and not more than 490 nm besides alkaline earth halophosphate phosphors 15a, 15b are used for the first phosphor group, the phosphor emitting the fluorescence having the peak emission wavelength of not less than 491 nm and not more than 600 nm besides β-SiAlON phosphor 15c and Ca solid solution α-SiAlON phosphor 15d are used for the second phosphor group, and the phosphor emitting the fluorescence having the peak emission wavelength of not less than 601 nm and not more than 670 nm besides CASON phosphor 15e and CASN phosphor 15f are used for the third phosphor group. Thus, the peak emission wavelength of the light emitted from the light emitting device 12 is desirably not more than 425 nm.

Meanwhile, if the peak emission wavelength of the light emitted from the light emitting element 12 is too short, the spectrum trough between the peak of the emission spectrum of the light emitting element 12 and the peak of emission spectrum of the phosphor 15 becomes large and the emission spectrum of the light emitting device 1 is difficult to come close to the emission spectrum of the sunlight. Thus, the peak emission wavelength of the light emitted from the light emitting element 12 is desirably not less than 410 nm.

As shown in FIG. 1, the phosphor 15 may be included in the sealing resin 14. The phosphor 15 may also be included in a phosphor layer formed by coating the light emitting element may also include.

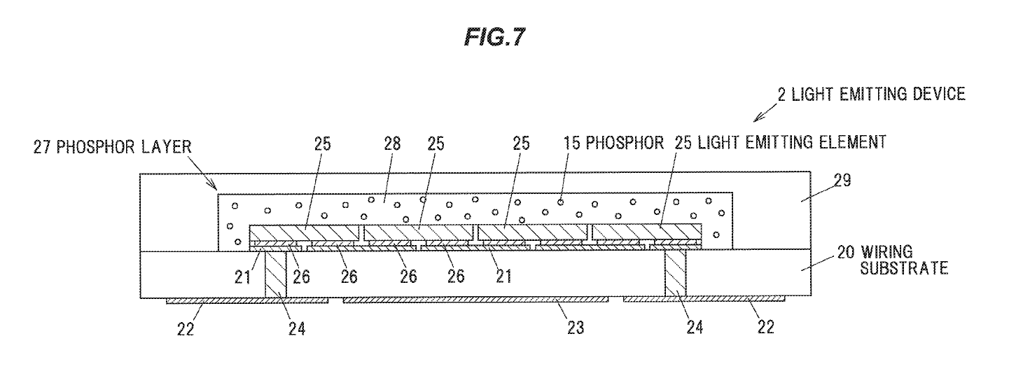

FIG. 7 is a cross sectional view showing a light emitting device 2 provided with the phosphor layer formed by coating that is the modification of the light emitting device 1.

The light emitting device 2 is provided with a wiring substrate 20, a light emitting element 25 disposed on the surface of the wiring substrate 20, a phosphor layer 27 coating the surface of the light emitting element 25, and a sealing material 29 coating the surface of the phosphor layer 27.

For example, the wiring substrate 20 is an AlN substrate. Wiring 21 comprising Cu is disposed on the top surface of the AlN substrate. A conductive pattern comprising Cu and a radiation pattern 23 are disposed on the bottom surface of the AlN substrate. The wiring 21 are electrically connected to the conductive pattern 22 through a via hole 24.

The light emitting element 25 has emission property corresponding to the light emitting element 12 of the light emitting device 1. An electrode 26 of the light emitting element 25 is connected to the wiring 21 by using Ag paste etc.

The phosphor layer 27 is formed on the light emitting element 25 by coating. The phosphor layer 27 is provided with binder resin 28 and the phosphor 15 included in the binder resin 28.

Since the sealing resin is normally formed by potting when the phosphor 15 is included in the sealing resin 14 as with the light emitting device 1, the concentration of the phosphor 15 is limited so as to keep viscosity capable of potting (for example, the concentration of the phosphor 15 in the sealing resin 14 is not less than 25 and not more than 55 percent by mass). This configuration tends to be used for a surface mount device (SMD) type light emitting device such as the light emitting device 1.

The resin for coating can increase the viscosity compared to the resin for potting. Thus, the concentration of the phosphor 15 in the binder resin 28 of the phosphor layer 27 of the light emitting device 2 formed by coating can be higher than the concentration of the phosphor 15 in the sealing resin 14 of the light emitting device 1 formed by potting (for example, the concentration of the phosphor 15 in the binder resin of the phosphor layer 27 is not less than 70 and not more than 80 percent by mass). This configuration tends to be used for a chip on board (COB) type light emitting device such as the light emitting device 2.

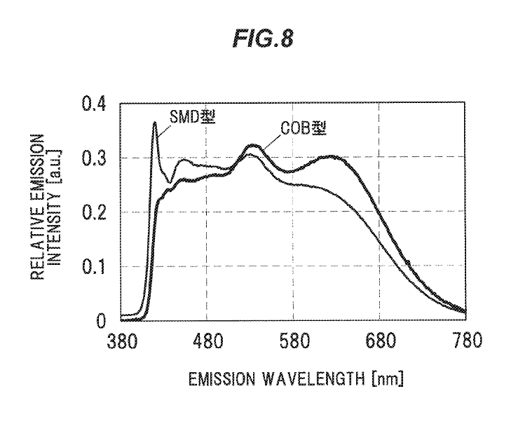

FIG. 8 is a graph chart showing emission spectra of the SMD type light emitting device 1 of which the phosphor 15 is included in the sealing resin 14, and the COB type light emitting device 2 of which the phosphor 15 is included in the phosphor layer formed by coating. The light emitting elements 12 emitting the light having the peak emission wavelengths of 420 nm, and 422 nm are respectively used for the light emitting devices 1, 2.

For these light emitting devices 1, 2, alkaline earth halophosphate phosphors 15a, 15b, β-SiAlON phosphor 15c, Ca solid solution α-SiAlON phosphor 15d, CASON phosphor 15e, and CASN phosphor 15f are used as the phosphor 15. Table 5 described below shows the concentration of the phosphor 15 and the concentration of each phosphor included in the phosphor 15 in the SMD type light emitting device 1 and the COB type light emitting device 2.

TABLE 5

| | Phosphor concentration | |
|---|---|---|
| | in resin (percent by mass) | |
| | SMD type | COB type |
| Phosphor 15 | 44.8 | 76.3 |
| Alkaline earth halophosphate phosphor 15a | 29.7 | 20.0 |
| Alkaline earth halophosphate phosphor 15b | 60.6 | 65.6 |
| β-SiAlON phosphor 15c | 3.6 | 4.7 |
| Ca solid solution α-SiAlON phosphor 15d | 3.1 | 1.6 |
| CASON phosphor 15e | 2.3 | 7.3 |
| CASN phosphor 15f | 0.8 | 0.9 |

An amount of the phosphor 15 above the light emitting element 12 in the SMD type light emitting device 1 of which the phosphor 15 is included in the seal resin 14 is less than the amount of the phosphor 15 above the light emitting element 12 in the COB type light emitting device 2 of which the phosphor 15 is included in the phosphor layer formed by coating caused by the difference in the resin forming methods described above. Thus, peak intensity of the emission spectrum by emission from the light emitting element 12 at a left side end increases.

The color rendering indexes Rf, Rg of the emission spectrum in the SMD type light emitting device 1 shown in FIG. 8 are respectively 97, 100. The color rendering indexes Rf, Rg of the emission spectrum in the COB type light emitting device 2 are respectively 98, 100. Each color rendering index is excellent.

That is, even if the phosphor 15 is included in the sealing resin 14, or the phosphor 15 is included in the phosphor layer formed by coating, the light emitting device according to the present embodiment can emit the light close to the sunlight that is excellent in the color rendering property by adjusting combination ratio of at least two types of phosphors included in the first phosphor group, at least two types of phosphors included in the second phosphor group, and at least two types of phosphors included in the third phosphor group, which are included in the phosphor 15.

### Advantageous Effects of the Embodiment

According to the above embodiment, the light emitting device that is excellent in color rendering property so as to emit a light closer to the sunlight than the light emitted from the known light emitting device can be provided.

Although the embodiments have been described, the invention is not intended to be limited to the embodiments. The various kinds of modifications can be implemented without departing from the gist of the invention. For example, the structure of the light emitting element is not limited to the structure shown in the embodiment as long as the light emitting device is provided with the light emitting element and the phosphor 15.

Also, the claimed invention is not intended to be limited to the embodiments. Further, it should be noted that all combinations of the features described in the embodiments and the examples are not necessary to solve the problems of the invention.

What is claimed is:

1. A light emitting device, comprising:
a first phosphor group comprising at least two types of phosphors emitting a fluorescence having a peak emission wavelength of not less than 445 nm and not more than 490 nm;
a second phosphor group comprising at least two types of phosphors emitting a fluorescence having a peak emission wavelength of not less than 491 nm and not more than 600 nm;
a third phosphor group comprising at least two types of phosphors emitting a fluorescence having a peak emission wavelength of not less than 601 nm and not more than 670 nm; and
a light emitting element emitting a light having a peak emission wavelength at a shorter wavelength side than the peak emission wavelength of the fluorescence emitted from the first phosphor group.

2. The light emitting device according to claim 1, wherein the peak emission wavelength of the light emitted from the light emitting element is not less than 410 nm and not more than 425 nm.

3. The light emitting device according to claim 1, wherein the light emitting device emits a light of which color rendering indexes Rf and Rg satisfy Rf≥90 and 95≤Rg≤105, respectively, where a base light is defined by a light having a color temperature of not less than 5000K and not more than 6500K.

4. The light emitting device according to claim 2, wherein the light emitting device emits a light of which color rendering indexes Rf and Rg satisfy Rf≥90 and 95≤Rg≤105, respectively, where a base light is defined by a light having a color temperature of not less than 5000K and not more than 6500K.

5. The light emitting device according to claim 1, wherein the first phosphor group comprises two types of alkaline earth halophosphate phosphors,
wherein the second phosphor group comprises β-SiAlON phosphor and Ca solid solution α-SiAlON phosphor, and
wherein the third phosphor group comprises CASON phosphor and CASN phosphor.

6. The light emitting device according to claim 2, wherein the first phosphor group comprises two types of alkaline earth halophosphate phosphors,
wherein the second phosphor group comprises β-SiAlON phosphor and Ca solid solution α-SiAlON phosphor, and
wherein the third phosphor group comprises CASON phosphor and CASN phosphor.

7. The light emitting device according to claim 3, wherein the first phosphor group comprises two types of alkaline earth halophosphate phosphors,
wherein the second phosphor group comprises β-SiAlON phosphor and Ca solid solution α-SiAlON phosphor, and
wherein the third phosphor group comprises CASON phosphor and CASN phosphor.
